(19) United States
(12) Patent Application Publication
(10) Pub. No.: US 2004/0137338 A1
(43) Pub. Date: Jul. 15, 2004

(54) Mask, exposure apparatus, and exposure method

(75) Inventors: Yasuhisa Inao, Atsugi-shi (JP); Ryo Kuroda, Kawasaki-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, TOKYO (JP)

(21) Appl. No.: 10/663,691

(22) Filed: Sep. 17, 2003

(30) Foreign Application Priority Data
Sep. 17, 2002 (JP) 269497/2002(PAT.)

(51) Int. Cl. G03F 9/00; G03C 5/00; G03B 27/00

(52) U.S. Cl. 430/5; 430/396; 430/311; 355/18

(57) ABSTRACT

Disclosed is an exposure method which includes the steps of closely contacting, to a workpiece, a mask having an opening formed with lengthwise directions extending in orthogonal directions, and projecting, onto the mask, exposure light being polarized in a direction other than the directions mentioned above.

### FIELD OF THE INVENTION AND RELATED ART

This invention relates generally to an exposure apparatus and, more particularly, it concerns a mask, an exposure apparatus and an exposure method usable for lithographic exposure of a workpiece such as, for example, a monocrystal substrate for semiconductor wafer or a glass substrate for liquid crystal display (LCD). The mask, the exposure apparatus and the exposure method according to the present invention can be used for production of various devices such as a semiconductor chip (e.g. IC or LSI), a display device (e.g. liquid crystal panel), a detecting device (e.g. magnetic head), and an image pickup device (e.g. CCD), for example.

Reduction in size and thickness of electronic devices has been particularly desired in recent years, and this has raised strictness in requirement for smallness of a semiconductor chip to be incorporated into such electronic devices. For example, as regards the design rule for the pattern of a mask or reticle (hereinafter, these words will be us d interchangeably), it would be reduced more and more in order to accomplish mass-production of a line-and-space (L&S) of 130 nm. The line-and-space is an image as projected upon a wafer, being in a state in which the line and the space have an even width, and thus it is a scale that represents the resolution of exposure. In a lithographic exposure process, the resolution, the registration precision and the throughput are three important parameters. The resolution means the minimum size that can be transferred exactly. The registration precision refers to the precision for superposing patterns one upon another on a workpiece. The throughput corresponds to the number or workpieces that can be processed per unit time.

Basically, exposure methods are classified into two methods, that is, a unit-magnification transfer method and a projection method. The transfer method includes a contact method in which a mask and a workpiece to be exposed are contacted to each other, and a proximity method in which they are separated from each other with a small clearance. The contact method can provide high resolution, but there is a possibility that dust particles or fractions of silicon are press-contacted to the mask surface to cause damage of the mask or scratch or fault of the workpiece. The proximity method can be free from such problems, but, if the clearance between the mask and the workpiece becomes smaller than the largest size of dust particles, similar damage of the mask may occur.

Projection methods have been proposed in consideration of this, in which methods the distance between a mask and a workpiece is enlarged more. Among such projection methods, scan type projection exposure apparatuses (also called a “scanner”) are currently prevalently used, in which, for improved resolution and enlarged exposure region, portions of a mask are exposed one by one and in which the mask and a wafer are continuously or interruptedly moved (scanned) in synchronism with each other, thereby to transfer the whole mask pattern onto the wafer.

Projection exposure apparatuses generally comprise an illumination optical system for illuminating a mask by use of a light flux emitted from a light source, and a projection optical system disposed between a mask and a workpiece to be exposed. In the illumination optical system, in order to obtain a uniform illumination region, the light flux from the light source is introduced into a light integrator such as a fly's eye lens having a plurality of rod lenses, for example, and a light exit surface of the light integrator operates as a secondary light source surface to Koehler—illuminate the mask surface through a condenser lens.

The resolution R of a projection exposure apparatus is given by the following equation, on the basis of the wavelength λ of a light source and the numerical aperture (NA) of the exposure apparatus.

R=k₁×[λ/NA] (1)

It is seen from this that, by shortening the wavelength more and more or by enlarging the NA more and more, the resolution can be improved more.

On the other hand, the focus range in which a certain imaging performance can be held is called a depth of focus, and the depth of focus DOF is given by the following equation.

DOF=k₂×[λ/NA^{2]} (2)

It is seen from this that, by shortening the wavelength more and more or by enlarging the NA more and more, the depth of focus becomes smaller. If the depth of focus is small, the focus adjustment becomes difficult to accomplish, and the flatness of a substrate or focus precision should be improved. Basically, therefore, the depth of focus should desirably be larger.

It would be understood from equations (1) and (2) that shortening the wavelength, rather than the NA, is effective. For this reason, in recent years, light sources are changing from conventional ultra-high pressure Hg lamps to short-wavelength KrF excimer lasers (wavelength is about 248 nm) or ArF excimer lasers (wavelength is about 193 nm).

However, the proportional constants k₁ and k₂ usually take a value of about 0.5 to 0.7. Even if a certain resolution enhancing method such as a phase shift method is used, it would not go beyond about 0.4. Therefore, it is difficult to improve the resolution by decreasing the proportional constant. Further, in projection exposure apparatuses, it is said that generally the resolution has its limit approximately at the wavelength of a light source used. Even where an excimer laser is used, it is difficult for a projection exposure apparatus to form a pattern not greater than 0.10 μm. Additionally, if there is any light source having shorter wavelength present, optical materials to be used for the projection optical system (i.e. lens glass materials) could not transmit exposure light of such shorter wavelength, and thus (because of resultant failure of projection upon a workpiece to be exposed) the exposure would end in failure. More specifically, almost all the glass materials have a transmissivity nearly equal to zero, in the deep ultraviolet region. Synthetic quartz which can be produced by use of a special production method can meet exposure light of a wavelength of about 248 nm. However, the transmissivity of it decreases steeply in regard to the wavelength not greater than 193 nm. For these reasons, it is very difficult to develop a practical glass material having a sufficiently large transmissivity to exposure light of a wavelength not greater than 150 nm, corresponding to a fine pattern of 0.10 μm or narrower. Furthermore, in addition to the transmissivity, a glass material to be used in the deep ultraviolet region must satisfy certain conditions in respect to plural standpoints such as durability, refractivity, uniformness, optical distortion, machinability and so on. These factors also make the development of a practical glass material difficult.

To such problem, exposure apparatuses which are based on the principle-of near-field optical microscope (Scanning Near-Field Optical Microscope: SNOM) have been recently proposed as the measure for enabling microprocessing with an order not greater than 0.10 μm. This is an apparatus in which, by use of near-field light seeping or escaping from small openings having a size not greater than 100 nm, for example, the workpiece (or a resist applied to it) is locally exposed thereby to exceed the limit of the wavelength of light. However, in such lithographic apparatus based on SNOM structure, the microprocessing operation is carried out using one or a few processing probes in a single continuous drawing stroke. The throughput is therefore very low.

As a solution for such problem, a transfer method has been proposed in which method a pattern of an optical mask as a whole is transferred to a resist in a single operation, by use of near-field light escaping from the optical mask having small openings, for example, formed therein. In order to perform the exposure process based on the near-field light, the clearance between a mask and a resist surface should be kept to be not greater than 100 nm. Actually, however, to keep the clearance between the mask surface and the resist surface to be not greater than 100 nm throughout the whole mask surface is difficult to accomplish, because of the limit of the surface precision of the mask or the substrate and due to tilt or the like involved in the positional alignment between the mask and the substrate. Any irregularity in clearance between the mask and the substrate may cause non-uniformness of exposure pattern or local crush of the resist by the mask. As a solution for such problem, U.S. Pat. No. 6,171,739 proposes a method in which a mask being elastically deformable in a direction of a normal to the mask surface is press-contacted to and separated from a resist, in an increased pressure and a reduced pressure, thereby to secure the clearance between the mask and the resist surface.

Japanese Laid-Open Patent Application No. 2000-112116 and a paper “Sub-diffraction-limited patterning using evanescent near-field optical lithography”, by M. M. Alkaisi et al, Appl. Phys. Lett. vol. 75, No. 22 (1999), have reported that the intensity of near-field light escaping from small openings changes between a case where light being polarized in a direction perpendicular to the lengthwise direction of the small opening is incident and a case where light being polarized in a direction parallel the lengthwise direction is incident.

Thus, in a lithographic exposure process using near-field light, there is a possibility that, if the exposure is carried out without controlling the polarization of exposure light, the intensity of near-field light leaking from the small openings formed in a mask changes in dependence upon the direction of polarization of exposure light with respect to the lengthwise direction of the small opening, thereby to cause non-uniformness in exposure pattern. Japanese Laid-Open Patent Application No. 2000-112116 thus proposes a mask by which polarization of exposure light can be controlled. This mask is provided with polarizer means arranged to produce an electric-field component parallel to the lengthwise direction of the small opening of the mask, such that near-field light is produced by exposure light being polarized in a particular direction with respect to the lengthwise direction of the small opening.

In the mask proposed in Japanese Laid-Open Patent Application No. 2000-112116, every mask to be used should have such polarizer means. Therefore, as compared with a mask without such polarizer, the productivity is low and the cost is high. The cost of the mask may cause an increase in the cost of semiconductor products. Also, if the exposure process is attended by mask manufacturing process, the throughput may be lowered.

### SUMMARY OF THE INVENTION

It is accordingly an object of the present invention to provide a mask, an exposure apparatus and/or an exposure method by which at least one of the problems described above can be solved or reduced.

In accordance with an aspect of the present invention, there is provided An exposure method, comprising the steps of: closely contacting, to a workpiece, a mask having an opening formed with lengthwise directions extending in orthogonal directions; and projecting, onto the mask, exposure light being polarized in a direction other than the directions mentioned above. With this exposure method, the intensity of near-field light escaping from the opening can be made even.

In accordance with another aspect of the present invention, there is provided an exposure mask, comprising: a mask base material supported by a substrate and being effective to transmit exposure light therethrough; a light blocking film formed on the mask base material and being effective to block the exposure light; and an opening formed in the light blocking film and having its lengthwise directions extending in mutually orthogonal directions. With this exposure mask, where exposure light having a polarization direction with 45°, for example, with respect to the opening is projected, through the openings having lengthwise directions extending only in the mutually orthogonal directions, the exposure light can be separated into polarized lights of the same intensity. Therefore, near-field light of even strength can be produced.

In accordance with a further aspect of the present invention, there is provided an exposure apparatus based on near-field light, comprising: light source means for emitting light to illuminate a mask having an opening formed with lengthwise directions extending in orthogonal directions; and a polarization system disposed between the mask and said light source means, for polarizing the light in a direction other than the directions mentioned above. Similar functions as described above are attainable with this exposure apparatus.

In accordance with a yet further aspect of the present invention, there is provided an exposure apparatus based on near-field light, wherein it comprises circularly polarized light projecting means for projecting, onto a mask having an opening formed with lengthwise directions extending in plural directions, exposure light having a circularly polarized component. With this exposure apparatus, since the exposure light contains a circular polarization component, uniform electric field components can be applied to openings having lengthwise directions extending in plural directions. Therefore, the intensity of near-field light escaping from the opening can be made even.

In accordance with a yet further aspect of the present invention, there is provided a device manufacturing method comprising the steps of exposing a workpiece by use of an exposure apparatus such as recited above, and performing a predetermined process to the exposure workpiece. The coverage of a claim directed to a device manufacturing method having a similar function as of an exposure apparatus described above, applies to a device itself which may be an intermediate product or a final product. The device may include a semiconductor chip, such as LSI or VLSI, a CCD, an LCD, a magnetic sensor and a thin film magnetic head, for example.

With a mask, an exposure apparatus and an exposure method according to the present invention, the intensity of near-field light escaping from a small opening can be made even without the provision of an analyzer upon a mask. Thus, the productivity of optical mask can be improved, and the cost can be reduced. Therefore, in accordance with the present invention, an exposure apparatus based on near-field light with small exposure non-uniformness can be accomplished with use of a lower-cost mask.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIG. 1 is a schematic and sectional view of an exemplary exposure apparatus according to the present invention.

FIG. 2A is a schematic and plan view of a mask shown in FIG. 1, and FIG. 2B is a schematic and sectional view of the mask.

FIG. 3 is a schematic and plane view for explaining the relation between a small opening and the direction of polarization of exposure light.

FIG. 4 is a schematic and plane view for explaining the relation between a small opening and the direction of polarization of exposure light.

FIG. 5 is a schematic and plan view of a main portion of small openings formed in a mask shown in FIG. 2.

FIG. 6 is a schematic and sectional view of an exposure apparatus, which corresponds to a modified form of the exposure apparatus shown in FIG. 1.

FIG. 7A is a schematic and plan view of a mask shown in FIG. 6, and FIG. 7B is a schematic and sectional view of the mask.

FIG. 8 is a schematic and plan view for explaining the relation between small openings and exposure light having a polarization characteristic of circularly polarized light.

FIG. 9 is a schematic and sectional view of an exposure apparatus in a case where a light source which emits linearly polarized light is used in a light source unit.

FIG. 10 is a flow chart for explaining manufacturing processes for the production of devices such as a semiconductor chip (IC or LSI), LCD, and CCD, for example.

FIG. 11 is a flow chart for explaining details of a wafer process at step 4 in FIG. 10.

### DESCRIPTION OF THE PREFERRED EMBODIMENTS

In an exposure method according to an aspect of the present invention, it comprises the steps of: closely contacting, to a workpiece, a mask having an opening formed with lengthwise directions extending in orthogonal directions; and projecting, onto the mask, exposure light being polarized in a direction other than the directions mentioned above. With this exposure method, the intensity of near-field light escaping from the opening can be made eve. The method may further comprise detecting the lengthwise direction of the opening of the mask, and generating the exposure step on the basis of the detection. In the projecting step, exposure light being polarized in a direction with an angle of approximately 45° with respect to the lengthwise direction of the opening, may be projected onto the mask. The mask may have an opening formed only in mutually orthogonal directions.

In an exposure mask according to another aspect of the present invention, the exposure mask comprises a mask base material supported by a substrate and being effective to transmit exposure light therethrough; a light blocking film formed on the mask base material and being effective to block the exposure light; and an opening formed in the light blocking film and having its lengthwise directions extending in mutually orthogonal directions. With this exposure mask, where exposure light having a polarization direction with 45°, for example, with respect to the opening is projected, through the openings having lengthwise directions extending only in the mutually orthogonal directions, the exposure light can be separated into polarized lights of the same intensity. Therefore, near-field light of even strength can be produced. The light blooding film may have a mark which mark bears information regarding the lengthwise direction of the opening.

In accordance with a further aspect of the present invention, there is provided an exposure apparatus based on near-field light, comprising: light source means for emitting light to illuminate a mask having an opening formed with lengthwise directions extending in orthogonal directions; and a polarization system disposed between the mask and said light source means, for polarizing the light in a direction other than the directions mentioned above. The apparatus may further comprise a detecting system for detecting the lengthwise direction of the opening, wherein said detecting system includes polarization control means for controlling the polarization direction of th light at an angle of 45° with respect to the lengthwise direction of the opening, on the basis of the detection made by said detecting system. The mask may have an opening formed only in mutually orthogonal directions. Similar functions as described above are attainable with this exposure apparatus.

In accordance with a yet further aspect of the present invention, there is provided an exposure apparatus based on near-field light, wherein it comprises circularly polarized light projecting means for projecting, onto a mask having an opening formed with lengthwise directions extending in plural directions, exposure light having a circularly polarized component. With this exposure apparatus, since the exposure light contains a circular polarization component, uniform electric field components can be applied to openings having lengthwise directions extending in plural directions. Therefore, the intensity of near-field light escaping from the opening can be made even.

In accordance with a yet further aspect of the present invention, there is provided a device manufacturing method comprising the steps of exposing a workpiece by use of an exposure apparatus such as recited above, and performing a predetermined process to the exposure workpiece. The coverage of a claim directed to a device manufacturing method having a similar function as of an exposure apparatus described above, applies to a device itself which may be an intermediate product or a final product. The device may include a semiconductor chip, such as LSI or VLSI, a CCD, an LCD, a magnetic sensor and a thin film magnetic head, for example.

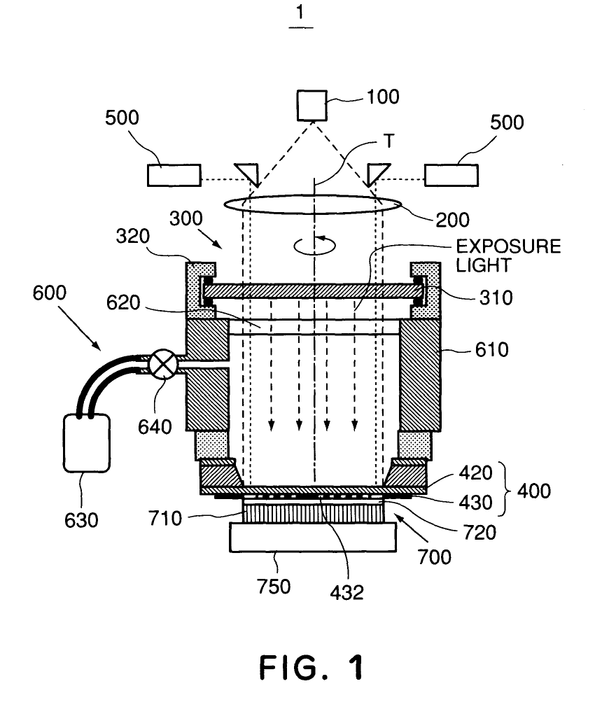

Referring now to the attached drawings, an exemplary exposure apparatus of the present invention will be explained. FIG. 1 is a schematic and sectional view of an exemplary exposure apparatus of the present invention. As shown in FIG. 1, the exposure apparatus 1 comprises a light source unit 100, a collimator lens 200, a polarization system 300, a mask 400, a detecting system 500, a pressure adjusting system 600, and a plate 700.

The exposure apparatus 1 operates, with use of the mask 400 corresponding to the whole surface of the plate 700, to perform unit-magnification batch exposure to transfer a predetermined pattern formed on the mask 400 onto the plate 700. However, the present invention can be used with a mask 440 smaller than the plate 700, and it can be applied to various exposure methods such as a step-and-repeat exposure method in which exposure of a zone of the plate 700 is repeated while changing the position of the plate 700, or a step-and-scan exposure method. The step-and-scan exposure method is a method in which the mask 400 and the plate 700 are continuously scanned with respect to exposure light projected thereto to transfer the pattern of the mask 400 onto the plate, and in which,-after completion of exposure of a single shot, the plate 700 is moved stepwise to move a subsequent shot to the exposure region. The step-and-repeat exposure method is a method in which, for each batch exposure of a shot of the plate 700, the plate 700 is moved stepwise to move a subsequent shot to the exposure region.

The light source unit 100 has a function for generating illumination light for illuminating the mask 300 which has a circuit pattern to be transferred. As an example, a laser which emits ultraviolet light or soft X-rays may be used as the light source. The laser may be ArF excimer laser of a wavelength of about 193 nm, KrF excimer laser of a wavelength of about 248 nm, or F2 excimer laser of a wavelength of about 153 nm, for example. However, the laser is not limited to excimer lasers, and YAG laser may be used, for example. Also, the number of lasers is not limited. Further, the light source to be used is not limited to lasers, and lamps such as one or plural Hg lamps or Xenon lamps may be used.

The collimator lens 200 functions to transform the illumination light into parallel light, and to introduce it into a pressurized vessel of the pressure adjusting system 600.

The polarization system 300 functions to polarize the exposure light from the light source unit 100. More specifically, the polarization system 300 has a polarization function for setting, on the basis of the direction of polarization of the exposure light as determined by the detecting system to be described later, the direction of polarization of the exposure light approximately at an angle 45° with respect to small openings 432 formed on the mask 400. The polarization system 300 has a polarizer 310 and driving means 320. The polarizer 310 is disposed to have a rotational axis T at the center of the mask 400, and it is held by the driving means 320 rotatably about the rotational axis T. As regards the polarizer 310, any element may be used provided that it can polarize the exposure light, such as polarization beam splitter, polarization plate, grid polarizer of metal thin wires, or mirror, for example. The driving means 320 holds the polarizer 310 horizontally (i.e. along the x-y plane) relative to the mask 400. It has an ultrasonic motor, for example, to rotate the polarize=310 relative to the mask 400, horizontally about the rotational axis T.

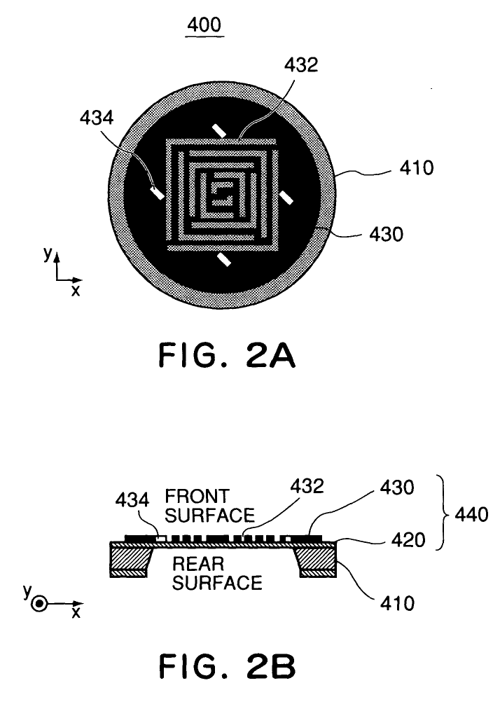

As shown in FIGS. 2A and 2B, the mask 400 has a mask supporting member 410, a mask base material 420, and a light blocking film 430 The mask base material 420 and the light blocking film 430 constitute a thin film 440 which is elastically deformable. Here, FIG. 2A is a schematic plan view of the mask 400 shown in FIG. 1, and FIG. 2B is a schematic and sectional view of the same. FIG. 2A illustrates a plan view of the mask 400, at its front surface side on which the light blocking film 430 is provided. The mask 400 is arranged so that a pattern which is defined by small openings 432 in the thin film 440 is transferred to a resist 720 at a unit magnification, on the basis of near-field light. The bottom face of mask as viewed in FIG. 1 corresponds to the front surface of the mask 400 on which the light blocking film 430 is attached, and the mask is disposed outside the pressurized vessel 610 of the pressure adjusting system 600.

The mask supporting member 410 supports the thin film 440 which comprises the mask base material 420 and the light blocking film 430, and the mask supporting member is fixed (by adhesion, for example) to the bottom of the pressurized vessel 610 of the pressure adjusting system 600 shown in FIG. 1. The mask supporting member 410 comprises a member that can maintain pressure tightness to pressure changes in the pressurized vessel 610 as well as gas tightness of the pressurized vessel 610. In this embodiment, the mask supporting member 410 is provided at the outer periphery of the mask 400.

The mask base material 420 comprises an elastic material such as Si3N or SiO2, for example, that can produce flexure by elastic deformation, in a direction of a normal to the mask surface, that is, in the thickness direction. Also, it is made of a material that can transmit the exposure light. Because the mask base material 420 is made of an elastic material, elastic deformation of the thin film 440 is enabled, as will be described later.

The light blocking film 430 is provided on the mask base material 420 with a film thickness of about 10 to 100 nm, and it comprises a metal film or any other film having a light blocking property. As shown in FIG. 2A, the light blocking film 430 has small openings 432 having a function for defining a desired pattern and for producing near-field light escaping therefrom, and index marks 434. The portions where the small openings are formed are open, while the remaining portions block the exposure light. In order to increase the intensity of the near-field light escaping from the small openings 432, the thickness of the light blocking film 430 should be small. However, if the light blocking film 430 is too thin, it may cause leakage of light from a portion other than the small openings 432. The film thickness range of the light blocking film 430 in this embodiment is appropriate to maintain good near field and light blocking property.

If the surface of the light blocking film 430 at a side to be contacted to the resist 720 is not flat, the film can not be well closely contacted to the resist 720 and it may cause non-uniform exposure. For this reason, the surface irregularity of the light blocking film 430 should be kept, at least, not greater than about 100 nm, more preferably, not greater than about 10 nm.

The small openings 432 may define the same patterns or different patterns. As shown in FIG. 2A, the small openings 432 have their lengthwise directions extending only in two directions, that is, x and y directions. It should be noted there that, although in this embodiment the lengthwise directions of the small openings 432 extend in x and y directions, the elongation directions are not limited to x and y directions. What is required is that the lengthwise directions of the small openings 432 extend in two orthogonal directions (e.g. L shaped).

The lithography which is based on near-field light can transfer the pattern at a unit magnification. Therefore, the patterns to be defined by the small openings 432 should be formed with a size of about 1 to 100 nm, which is small as compared with the wavelength of the exposure light from the light source unit 100. If the width of the patterns of the small opening 432 is larger than 100 nm, not only the near-field light but also direct light having strong light intensity can transmit the mask 400, with an undesirable result that the light quantity level changes largely with th pattern. Also, if the width is less than 1 nm, the exposure itself is not unattainable, but the intensity of near-field light escaping from the mask 400 becomes very small so that, impractically, it takes a long time to complete the exposure.

The intensity of the near-field light escaping from the small openings 432 differs with the size of the small openings. Thus, if the size of the small openings is uneven, the degree of exposure of the resist 720 becomes uneven which makes it difficult to accomplish uniform pattern formation. In order to avoid such a problem of uniformness, the widths of the patterns of the small openings 432 formed on the mask 400 to he used in a single near-field light exposure process should desirably be made even.

The index marks 434 have a function for indexing the polarization direction of exposure light with regard to the lengthwise direction of the small openings 432. More specifically, the index marks 434 contain information for detecting the lengthwise direction of the small openings 432. In this embodiment, as shown in FIG. 2A, the index marks 434 are formed on the light blocking film 430, at an angle 45° with respect to the small openings 432 of the mask 400 Thus, once the lengthwise direction of the small openings 432 and the polarization direction of the exposure light are registered with each other, the polarization direction of the exposure light can be set at an angle 45° with respect to the lengthwise direction of the small openings 432. As a matter of course, the index marks 434 are formed in a portion not influential to the exposure, that is, a portion separate from the portion where the small openings are formed.

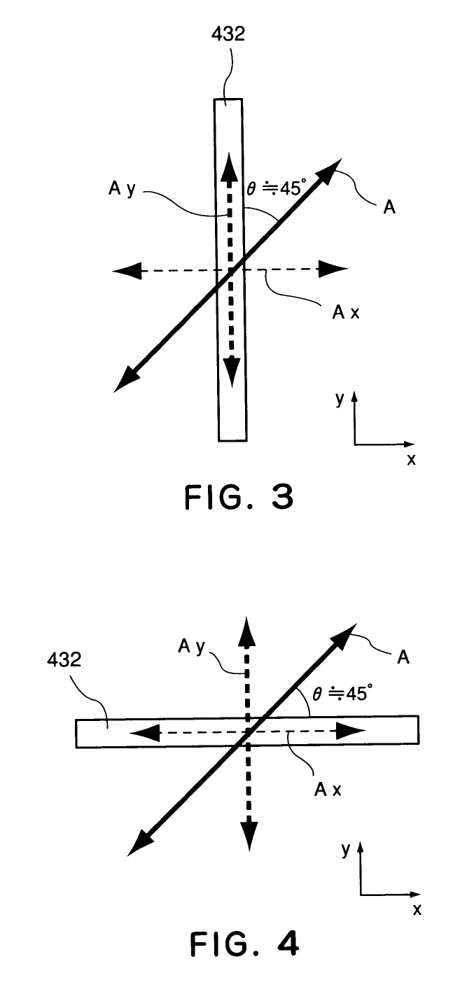

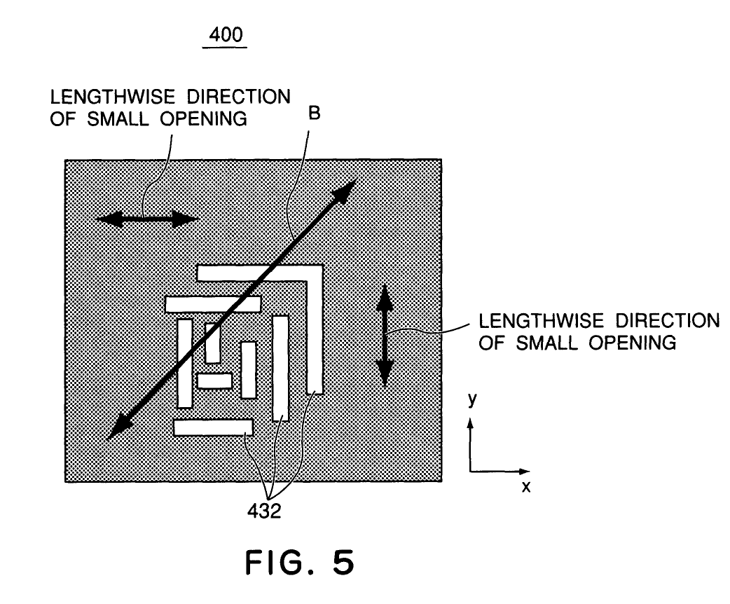

Referring now to FIGS. 3-5, the small openings 432 of the mask 400 and the polarization direction of the exposure light will be explained. FIGS. 3 and 4 are schematic and plan views, illustrating the relation between a small opening 432 and the polarization direction A of the exposure light. FIG. 5 is a schematic and plane view of a main portion of small openings 432 of the mask 400 shown in FIG. 2, and it illustrates the relation between the small openings 432 and the polarization direction A of the exposure light.

As shown in FIG. 3, the light having a polarization direction A with an angle of about 45° within the mask 400 surface, with respect to the lengthwise direction (y direction) of the small opening 432, can be considered by splitting it into polarized light of x-direction component Ax and polarized light of y-direction component Ay, having the same intensity, with respect to the small opening 432. Similarly, as shown in FIG. 4, even if the lengthwise direction of the small opening 432 is in the x direction, the light having a polarization direction A with an angle of about 45° within the mask 400 surface, with respect to the lengthwise direction of the small opening 432, can be considered by splitting it into polarized light of x-direction component Ax and polarized light of y-direction component Ay, having the same intensity, with respect to the small opening 432.

As shown in FIG. 5, in the mask 400 of this embodiment, the small openings 432 have their lengthwise directions extending only in two directions, i.e. x and y directions. Thus, it has a mixture of small openings 432 shown in FIGS. 3 and 4 It means that the same exposure light is incident on the small openings 432 shown in FIGS. 3 and 4, and that the polarized light have the same intensity in both of the x-direction component and the y-direction component. Therefore, whichever the lengthwise direction of the small opening 432 extends in x direction or y direction, the intensity of the near-field light escaping from the small openings 432 becomes even. Namely, in the mask 400 according to this embodiment, the polarization direction of exposure light with respect to the lengthwise direction (x and y directions) of the small openings 432 is set at about 45°, by which the intensity of the near-field light escaping from the small openings 432 can be made even, without the provision of a polarizer in the mask 400.

The detecting system 500 detects the index marks 434 of the mask 400 by use of a CCD camera, for example. On the basis of detection of the index marks 434, the detecting system 500 reads the lengthwise direction of the small openings.432 of the mask 400 and determines the direction in which the exposure light should be polarized.

The pressure adjusting system 600 functions to facilitate good close-contact and separation between the mask 400 and the plate 700, more particularly, between the light blocking film 430 (small openings 432) of the thin film 440 and the resist 720. Where the surface of the light blocking film 430 and the surface of the resist 700 are completely flat, by contacting them, they can be closely contacted to each other throughout the whole surface. Practically, however, the light blocking film 430 and/or the resist 700 or a substrate 710 have surface irregularity or waviness. Therefore, only by simply approximating them and contacting them to each other, the resultant state would be distribution of closely-contacted portions and non-closely-contacted portions. In the non-closely-contacted portions, the small openings and the plate 700 are disposed out of the range in which the near-field light functions, such that non-uniform exposure would result. In consideration of this, in this embodiment, a pressure is applied by the pressure adjusting system 600 in a direction from the rear surface of the thin film 440 toward the front surface thereof, to cause elastic deformation of the thin film 440, thereby to press the thin film 430 against the resist 720. As a result of this, the thin film can be closely contacted to the resist, throughout the entire surface. Where the light blocking film 430 is to be separated from the plate 700, pressure application may be done inversely.

The pressure adjusting system 600 comprises a pressurized vessel 610, a light transmitting window 620 provided by a glass, for example, pressure adjusting means 630 and a pressure adjusting valve 640. The pressurized vessel 610 can keep its gas tightness, with cooperation with the light transmitting window 620, the mask 400 and the pressure adjusting valve 640. The pressurized vessel 610 is connected to the pressure adjusting means 630 through the pressure adjusting valve 640, such that the pressure inside the pressurized vessel 610 can be adjusted. The pressure adjusting means 630 may comprise a high-pressure pump, for example, and it can operate to increase the pressure inside the pressurized vessel 610 through the pressure adjusting valve 640. Further, the pressure adjusting means 630 includes an evacuation pump, not shown, and it can decrease the pressure inside the vessel 610 through the pressure adjusting valve 640.

The close contact between the light blocking film 430 and the resist 720 can be adjusted by adjusting the pressure of the pressurized vessel 610. Where the surface irregularity or waviness of the mask 400 surface or the surface of the resist 720 or substrate 710 is large, the pressure inside the vessel 610 may be set at a relatively high level to increase the adhesive force, by which uneven clearance with the mask 400 surface due to surface irregularity or waviness can be removed.

Alternatively, the front surface side of the mask 400 or the resist 720 or substrate 710 side may be disposed inside a reduced pressure vessel. In that occasion, due to the pressure difference with the atmospheric pressure which Is higher than the inside pressure of the reduced pressure vessel, a pressure is applied from the rear surface side of the mask 440 to the front surface side thereof, such that adhesion between the mask 400 and the resist 720 can be improved. Anyway, a pressure difference is provided to create a higher pressure at the rear surface side of the mask 400, as compared with the front surface side thereof. Where the surface irregularity or waviness of the mask 400 surface or the surface of the resist 720 or substrate 710 is large, the pressure inside the reduced pressure vessel may be set at a relatively low level to increase the adhesive force, by which uneven clearance with the mask 400 surface due to surface irregularity or waviness can be removed.

As a further alternative embodiment, the inside of the pressurized vessel 610 may be filled with a liquid which is transparent with respect to the exposure light, and the pressure of the liquid inside the vessel 610 may be adjusted by use of a cylinder (not shown).

The plate 700 comprises a substrate 701 such as a wafer, and a photoresist 720 applied to it. The plate 700 is mounted on a stage 750. The application of the resist 720 includes a pre-process, an adhesion enhancing agent applying process, a resist coating process, and a pre-baking process. The preprocess includes washing and drying, for example. The adhesion enhancing agent applying process is a surface property improving process (hydrophobic process based on surface active agent coating) for improving the adhesion between the photoresist 720 and the substrate 710, and an organic film such as HMDS (Hexamethyl-disilazane), for example, is applied or vapor processed. The pre-baking process is a baking (sintering) process, while it is mild as compared with that to be carried out after the development, and it removes the solvent.

The substrate 710 may be chosen from a wide variety of materials, such as, for example, a semiconductor substrate such as Si, GaAs, or InP, an insulative substrate such as glass, quartz, or BN, or such a substrate as described but having a film of metal, oxide, nitride or the like. However, since it should be closely contacted to the mask 400 throughout the entire exposure region with a clearance preferably not greater than 10 nm and, at least, not greater than 100 nm, the substrate 710 to be chosen should be flat as much as possible.

Similarly, as regards the shape of the resist 720, it should be flat with the surface irregularity being small.

The intensity of the near-field light leaking from the thin film 440 decreases exponentially as becoming remote from the mask 400 and, therefore, it is difficult to perform exposure of the resist 720 up to a depth of 100 nm or more. Also, the near-field light is distributed as being scattered within the resist 720. Therefore, taking into account the possibility that the exposure pattern width is enlarged, the thickness of the resist 720 should be made, at least, not greater than about 100 nm, and it should be made thin as much as possible.

As described above, the material of the resist 720 and the coating method therefor should be chosen so that preferably the film thickness and the surface irregularity of the resist 720 become not greater than about 10 nm and, at least, not greater than about 100 nm. For example, a general-purpose resist material may be solved into a solvent being effective to reduce the viscosity as much as possible, and it may be applied by spin coating into a coating film of thin and uniform thickness. Another optical resist material and a coating method may be Langmuir-Blodgett's technique (LB method) that a monomolecular film in which amphipathic resist material molecules having a hydrophobic group, a hydrophilic group and a functional group in a single molecule are placed on the water surface is scooped off onto a substrate by predetermined times, thereby to form an accumulated film of monomolecular films on the substrate. A further alternative method is a self-arraying monomolecular film forming method (SAM method) in which, an the basis of physical attraction or chemical bonding of only a single molecular layer to a substrate within a solvent or a gaseous phase, a monomolecular film of an optical resist material is formed on the substrate. The LB method or SAM method is suitable since a very thin resist film can be formed thereby, with an even thickness and good flatness.

In the lithographic exposure using near-field light, during the exposure process the clearance between the mask 400 and the resist 720 or substrate 710, throughout the entire surface, should be maintained uniform and, at least, not greater than about 100 nm. For this reason, regarding the substrate 710, those having been already treated by another lithographic process or processes and having a surface-step pattern of 100 nm or more defined thereon, are not preferable. Thus, a substrate 710 not treated by many processes, that is, a substrate at the process initial stage and thus being flat as much as possible is desirable. Where the exposure process based on near-field light is combined with any other lithographic process, the exposure process based on the near-field light should desirably be done at a stage earlier as much as possible.

The resist 720 and the mask 400 are closely contacted to each other, during the exposure operation, within a range in which the near-field light functions, that is, in this embodiment, in a range from zero to the wavelength of the exposure light emitted from the light source unit 100. Generally, exposure light does not pass through a small opening 432 being smaller than the wavelength of the exposure light, but there is near-field light escaping from the small opening 432. The near-field light is non-propagating light which is present only in a peripheral portion of the small opening 432, within a distance not greater than about 100 nm. The intensity of it decreases steeply as becoming away from the small opening 432. Thus, the small opening from which the near-field light escapes and the resist 720 are approximated relatively to each other up to a distance not greater than about 100 nm. For example, where the light source of the light source unit 100 uses a KrF excimer laser having a wavelength of about 248 nm or less, the distance between the mask 400 and the plate 700 should desirably be set to be not greater than about 124 nm, a half of the wavelength. Similarly, where the light source of the light source unit 100 uses ArF excimer laser of a wavelength of about 193 nm or less, the distance between the mask 400 and the plate 700 should desirably be set to be not greater than about 100 nm, a half of the wavelength.

The stage 750 is driven by external means (not shown), to two-dimensionally and relatively align the plate 700 with respect to the mask 400, and also to move the plate 700 in vertical directions as viewed in FIG. 1. The stage 750 of this embodiment moves the plate 700 between a loading/unloading position (not shown) and the exposure position shown in FIG. 1. At the loading/unloading position, a fresh plate 700 is loaded before exposure, and a plate 700 after exposure is unloaded.

For exposure, the stage 750 operates to position and align the plate 700 two-dimensionally and relatively with respect to the mask 400. After the alignment is completed, the stage 750 moves the plate 700 in a direction of a normal to the mask 400 surface, into a range that the clearance between the front surface of the mask 400 and the surface of the resist 720 becomes not greater than 100 nm, throughout the entire surface, and that they are closely contacted to each other once the thin film 440 is deformed elastically.

Subsequently, the mask 400 and the plate 700 are brought into close contact with each other. More specifically, first the pressure adjusting valve 640 is opened so that the pressure adjusting means 630 introduces a high pressure gas into the pressurized vessel 610. After the inside pressure of the vessel 610 increases, the pressure adjusting valve 640 is closed. As the inside pressure of the vessel 610 increases, it causes elastic deformation of the thin film 400 so that the film is pressed against the resist 720. As a result of this, the thin film 440 is closely contacted to the resist, within a range in which the near-field light can function to the resist 720, with a uniform pressure throughout the entire surface. Where a pressure is applied in the manner such as described above, in accordance with Pascal's principle, the repulsive force acting on between the thin film 440 and the resist 720 becomes uniform. This provides an advantageous effect that no large force is applied locally to the thin film 440 or the resist 720, and this prevents local breakage of the mask 400 or plate 700 thereby.

Subsequently, on the basis of the index marks 434 of the mask 400, the direction in which the exposure light should be polarized is detected by means of the detecting system 500. Then, the driving system 320 of the polarizing system 300 rotates the polarizer 310 about the rotational axis T, horizontally to the mask 400. Although in this embodiment the polarizer 310 is rotated, the polarizer 310 may be held fixed and, in place, the mask 400 may be rotated so that the small openings 432 have an angle of about 45° with respect to the polarization direction of the exposure light. However, in that occasion, the rotation of the mask 400 is carried out before the mask 400 and the plate 700 are closely contacted to each other. As a further alternative, the polarizer may not be used, and a laser of rectilinearly polarized light may be rotated in accordance with the index marks of the mask 400 while taking the direction of emission of the laser as a rotational axis, thereby to rotate the polarization direction to have an angle of about 45° with respect to the lengthwise direction of the small openings 432.

The exposure process is carried out in the state described just above. More specifically, exposure light emitted from the light source unit 100 and having been transformed by the collimator lens 200 into parallel light, is introduced into the pressurized vessel 610 through the polarizer 310 and the light transmitting window 620. Here, the exposure light has been polarized in a direction corresponding to the small openings 432 formed in the light blocking film 430, that is, the polarization direction of the exposure light has an angle 45° with respect to the lengthwise direction of the small openings 432. The light introduced into the vessel 610 passes through the mask 440 from the rear-surface side to the front-surface side thereof, that is, from the top to the bottom as viewed in FIG. 1, thereby to produce near-field light escaping from the pattern as defined by the small openings 432 of the thin film 440. The near-field light scatters within the resist 720, to expose the resist 720. If the thickness of the resist 720 Is sufficiently thin, the scattering of the near-field light within the resist 720 does not expand so widely, such that a pattern corresponding to the slits of the small openings 432, which are smaller than the wavelength of the exposure light, can be transferred to the resist 720.

As described above, the exposure process is carried out by use of exposure light having a polarization direction with an angle of about 45° with respect to the lengthwise direction of the small openings 432 of the mask. This assures that the intensity of the near-field light escaping from the small openings 432 becomes even such that, without the provision of a polarizer in the mask 400, non-uniformness of exposure of the resist 720 can be reduced effectively.

After the exposure, a valve (not shown) is opened and the inside of the pressurized vessel 610 is evacuated by means of an evacuation pump (not shown) of the pressure adjusting means 600, thereby to decrease the pressure of the vessel 610. Thus, due to elastic deformation, the thin film 440 is separated (or pealed) from the resist 720. Where the pressure is reduced in the manner described above, in accordance with Pascal's principle the repulsive force acting on between the thin film 440 and the resist 720 becomes uniform. This provides an advantageous effect that no large force is applied locally to the thin film 440 or the resist 720, and this prevents local breakage of the 400 or the plate 700 thereby.

Here, by controlling the pressure inside the pressurized vessel 610, the attracting force acting on between the mask 400 and the resist 720 or substrate 710, that is, tensile force between them, can be controlled. For example, where the attracting force between the mask surface and the resist or substrate surface is large, the pressure inside the pressurized vessel 610 may be set at a relatively lower level to increase the tensile force, thereby to facilitate the separation.

Subsequently, the plate 700 is moved by the stage 750 to the loading/unloading position, where it is replaced by a fresh plate 700, and similar operations are repeated thereafter.

Specific examples of the present invention will now be described.

### EXAMPLE 1

Now, a case where an exposure apparatus 1 operates to transfer a plurality of patterns (the same patterns) in a batch exposure process, will be explained. For manufacture of a mask 400, Si substrate (100) was chosen for a mask supporting member 410. Upon this Si substrate, SiN film as a mask base material 420 was formed with a thickness 500 nm, in accordance with LPCVD (Low Pressure Chemical Vapor Deposition) method. Further, upon the mask base material 420, a Cr film as a light blocking film 430 was formed with a thickness 50 nm, in accordance with a sputtering method. Small openings 432 (opening diameter not greater than 100 nm) of a size not greater than the wavelength of exposure light, were formed on the light blocking film 430 into a desired pattern, by means of electron-beam lithographic method. Namely, a Cr film was coated with an electron beam resist, and a pattern was formed on the electron beam resist by means of an electron beam. After the pattern was formed, in accordance with a dry etching method using CC14, the small openings 432 were formed in the Cr film.

As shown in FIG. 2A, the small openings of this embodiment have their lengthwise directions extending only in x and y directions. Namely, the small openings 432 are formed so that they have lengthwise directions extending in only two orthogonal directions. Subsequently, index marks 434 having a function for indexing the polarization direction of the exposure light with respect to the lengthwise direction of the small openings 432, were formed in the Cr film (light blocking film 430) in accordance with an electron beam lithographic method and a dry etching method, in the manner similar to the formation of the fine openings 432.

Subsequently, at the surface on the opposite side of the light blocking film 430, patterning with a size 26 mm×26 mm was carried out to that portion where the mask 400 should be produced. Then, SiN material in that portion was removed by RIE (Reactive Ion Etching) method using CF4 gas. The remaining SiN was used as an etching mask, the silicon was etched by use of an aqueous solution of 30 wt % potassium hydroxide, being warmed at 110° C., by which Si material only at that portion to be made into the mask 400 was removed. With the processes described above, a mask 400 supported by a silicon wafer was produced.

In this example, SiN is used as a base material 420 of the mask while Cr is used as a light blocking film 430. However, the concept of the present invention is not limited to use of a particular material. As regards the base material 420 of the mask, preferably, it should be a material being transmissive to exposure light and also it should provide a sufficient mechanical strength to the thin film 440. As regards the light blocking film 430, on the other hand, preferably, it should be a material having no influence upon the plate 700 and also be a material which does not transmit light of the wavelength to be used for the exposure. Additionally, it may preferably have a thickness by which light can be attenuated sufficiently.

A mask 400 having been produced in the manner described above, is mounted into an exposure apparatus 1 shown in FIG. 1.

Subsequently, the detecting system 500 detects the index marks 434 of the mask 400. In this embodiment, the index marks 434 are formed with an angle 45° with respect to the lengthwise direction of the small openings 432. Therefore, the exposure light is polarized in the lengthwise direction of the index marks 434. By means of the driving system 320, the polarizer 310 is rotated so that the polarization direction of the exposure light is set with an angle 45° with respect to the lengthwise direction of the small openings 432.

After this, in order to prepare close contact between the resist 720 (object to be exposed) and the mask 400, an alignment operation is carried out to between the mask 400 and the substrate 700. Then, a compressed air is introduced by the pressure adjusting means 630 into the pressurized vessel 610 at a pressure 40 kPa, whereby a pressure difference is produced between the front surface and the rear surface of the mask 400. Thus, the thin film is flexed and close contacted to the resist 720, uniformly at a clearance not greater than about 100 nm.

After the mask and the resist 720 are closely contacted to each other, light is projected from an Hg lamp of the light source unit 100, which can emit wavelengths 436 nm and 365 nm at a strong intensity. The light is then transformed into parallel light, by the collimator lens 200. The resultant parallel light is used as exposure light which is then polarized by a polarizer 310 in a direction of 45° with respect to the lengthwise direction of the small openings 432, and it is projected to the whole surface of the mask 400. Exposure light thus projected on the mask 400 escapes from the small openings 432 of the mask 400 surface, and near-field light of uniform intensity is produced. With this near-field light, the pattern of the small openings 432 was transferred by batch exposure, to the whole surface of the resist 720 without exposure non-uniformness.

For separation of the mask 440 from the plate 700, the inside pressure of the pressurized vessel 610 was lowered by the pressure adjusting means 630 to a pressure lower than the atmospheric pressure approximately by 40 kPa, and then the mask 400 and the plate 700 were separated from each other.

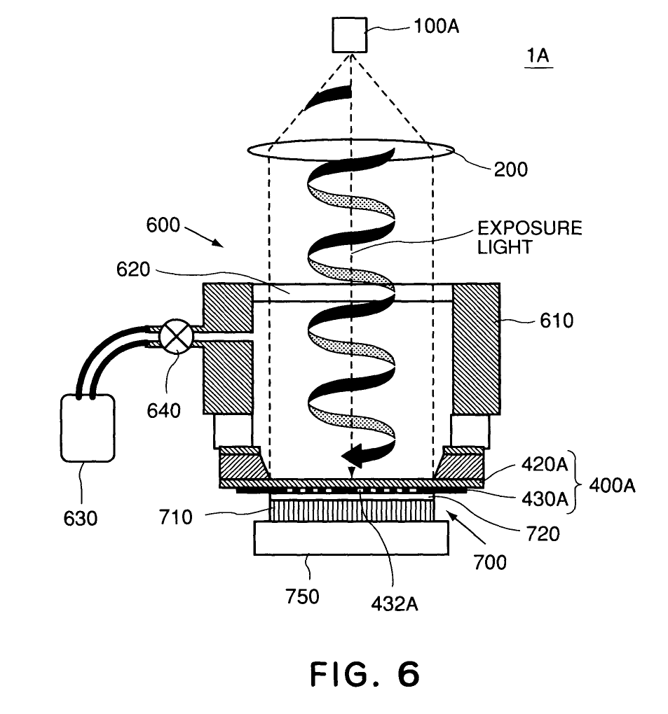

Referring now to FIGS. 6-9 an exposure apparatus 1A corresponding to a modified form of the exposure apparatus 1, will be explained. FIG. 6 is a schematic and sectional view of an exposure apparatus 1A corresponding to a modified form of the exposure apparatus 1 shown in FIG. 1. The exposure apparatus IA differs from the exposure apparatus 1 of FIG. 1, in the structure of a light source unit 100A and a mask 400A. Like numerals as those in FIG. 1 denote corresponding elements, and duplicate explanation will be omitted.

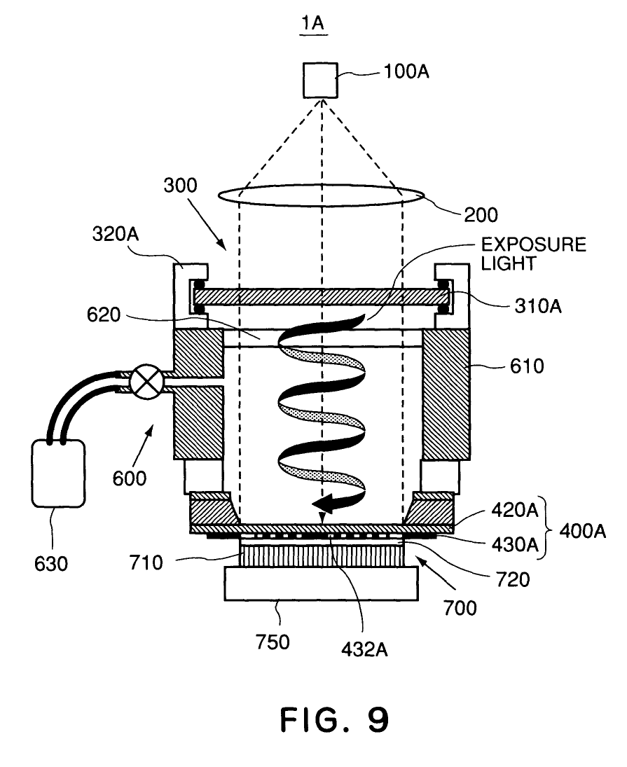

The light source unit 100A has a function for generating illumination light which illuminates the mask 400A having a circuit pattern to be transferred. For example, the light source thereof may comprise a Zeeman laser for emitting light having a polarization property of circular polarization. However, the light source to be used in the light source unit 100A is not limited to Zeeman laser. For example, as shown in FIG. 9, a laser which emits ultraviolet light or soft X-rays having a polarization property of linear polarization (e.g. ArF excimer laser of a wavelength about 193 nm, KrF excimer laser of a wavelength about 248 nm, or F2 excimer laser of a wavelength about 153 nm) may be used while the laser light may be circularly polarized by means of a circular polarization transforming system 300A. The circular polarization transforming system 300A may comprise, for example, a quarter waveplate 310A, and driving means 320A, and it functions to transform, into circularly polarized light, the light having a polarization property of linear polarization. The quarter waveplate 310A is drivingly held by the driving means 320A, and it functions to emit light after converting linearly polarized light into circular polarization. The driving means 320A holds the quarter waveplate 310A and rotates the same so that light, which is being exactly circularly polarized with respect to the polarization plane of the light emitted from the light source unit 100A, can be emitted from the quarter waveplate 310A. FIG. 9 is a schematic and sectional view of the exposure apparatus 1A where a light source which emits linearly polarized light is used in the light source unit 100A. Without using the quarter waveplate 310A, a Pockels cell which converts linearly polarized light into circularly polarized light in response to application of an electric field, may be used. Further, light being randomly polarized such as light from an Hg lamp may be transformed into linearly polarized light by use of a polarizer, and then it may be transformed into circularly polarized light by means of a quarter waveplate. Namely, the light emitted from the light source unit 100A is transformed into circularly polarized light, before it is projected on the mask 400A.

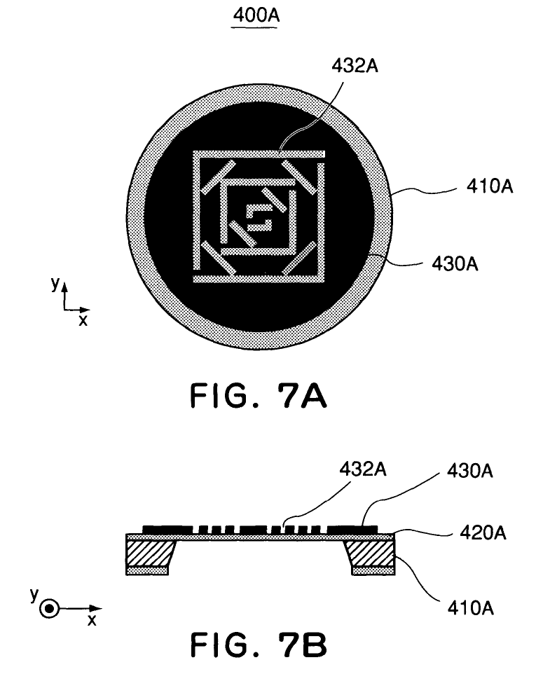

As shown in FIGS. 7A and 7B, the mask 400A has a mask supporting member 410A, a mask base material 420A, and a light blocking film 430A. The mask base material 420A and the light blocking film 430A constitute a thin film 440A which is elastically deformable. Here, FIG. 7A is a schematic plan view of the mask 400A shown in FIG. 6, and FIG. 7B is a schematic and sectional view of the same.

FIG. 7A illustrates a plan view of the mask 400A, at its front surface side on which the light blocking film 430A is provided. The mask 400A is arranged so that a pattern which is defined by small openings 432A in the thin film 440A is transferred to a resist 720 at a unit magnification, on the basis of near-field light. The bottom face of mask as viewed in FIG. 7 corresponds to the front surface of the mask 400A on which the light blocking film 430A is attached, and the mask is disposed outside the pressurized vessel 610 of the pressure adjusting system 600.

The mask supporting member 410A supports the thin film 440A which comprises the mask base material 420A and the light blocking film 430A, and the mask supporting member is fixed (by adhesion, for example) to the bottom of the pressurized vessel 610 of the pressure adjusting system 600 shown in FIG. 7. The mask supporting member 410A comprises a member that can maintain pressure tightness to pressure changes in the pressurized vessel 610 as well as gas tightness of the pressurized vessel 610. In this embodiment, the mask supporting member 410A is provided at the outer periphery of the mask 400A.

The mask base material 420A comprises an elastic material such as Si3N or SiO2, for example, that can produce flexure by elastic deformation, in a direction of a normal to the mask surface, that is, in the thickness direction. Also, it is made of a material that can transmit the exposure light. Because the mask base material 420A is made of an elastic material, elastic deformation of the thin film 440A is enabled, as will be described later.

The light blocking film 430A is provided on the mask base material 420A with a film thickness of about 10 to 100 nm, and it comprises a metal film or any other film having a light blocking property. As shown in FIG. 7A, the light blocking film 430A has small openings 432A having a function for defining a desired pattern and for producing near-field light escaping therefrom. The portions where the small openings are formed are open, while the remaining portions block the exposure light. In order to increase the intensity of the near-field light escaping from the small openings 432A, the thickness of the light blocking film 430A should be small. However, if the light blocking film 430A is too thin, it may cause leakage of light from a portion other than the small openings 432A. The film thickness range of the light blocking film 430A in this embodiment is appropriate to maintain good near field and light blocking property.

If the surface of the light blocking film 430A at a side to be contacted to the resist 720 is not flat, the film can not be well closely contacted to the resist 720 and it may cause non-uniform exposure. For this reason, the surface irregularity of the light blocking film 430A should be kept, at least, not greater than about 100 nm, more preferably, not greater than about 10 nm.

The small openings 432A may define the same patterns or different patterns. In the case of FIG. 7A, the small openings 432A define different patterns.

The lithography which is based on near-field light can transfer the pattern at a unit magnification. Therefore, the patterns to be defined by the small openings 432A should be formed with a size of about 1 to 100 nm, which is small as compared with the wavelength of the exposure light from the light source unit 100A. The pattern may have an arbitrary shape (e.g. L-shape or S-shape) as long as it is not greater than 100 nm. If the width of the patterns of the small openings 432A is larger than about 100 nm, not only the near-field light but also direct light having strong light intensity can transmit the mask 400A, with an undesirable result that the light quantity level changes largely with the pattern. Also, if the width is less than about 1 nm, the exposure itself is not unattainable, but the intensity of near-field light escaping from the mask 400A becomes very small so that, impractically, it takes a long time to complete the exposure

The intensity of the near-field light escaping from the small openings 432A differs with the size of the small openings. Thus, if the size of the small openings is uneven, the degree of exposure of the resist 720 becomes uneven which makes it difficult to accomplish uniform pattern formation. In order to avoid such a problem of uniformness, the widths of the patterns of the small openings 432A formed on the mask 400A to be used in a single near-field light exposure process should desirably be made even.

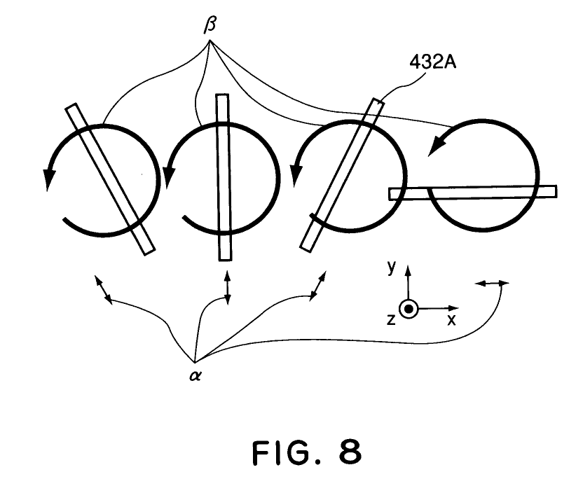

Here, referring to FIG. 8, the relation between the small openings 432A of the mask 400A and exposure light being polarized circularly, will be explained. FIG. 8 is a schematic and plane view which illustrates the relation between the small openings 432A of the mask 400A and exposure light being polarized circularly. This embodiment uses circularly polarized light, as the exposure light. Thus, all the polarized light components are included in the exposure light and, therefore, the angular dependence with respect to the lengthwise direction of the small openings 432A is eliminated. Namely, even if the lengthwise direction a of the small openings 432A is oriented in any direction such as x direction, y direction and an intermediate direction of them, as shown in FIG. 8, since the exposure light is circularly polarized light β, a uniform electric-field component can be applied to the small openings in every direction. As a result, it is able to disregard the intensity of the near-field light escaping from the small openings 432A, which is changeable between a case where light being polarized in a direction perpendicular to the lengthwise direction a of the small openings 432A is projected and a case where light being polarized in a parallel direction is projected. That is, it is able to disregard the polarization characteristic of the light with respect to the lengthwise direction of the small openings 432A. With this arrangement, the intensity of the near-field light escaping from the small openings 432A having lengthwise directions extending in an arbitrary direction on the mask 400A, can be made even.

For exposure, the stage 750 operates to position and align the plate 700 two-dimensionally and relatively with respect to the mask 400A. After the alignment is completed, the stage 750 moves the plate 700 in a direction of a normal to the mask 400A surface, into such range that the clearance between the front surface of the mask 400A and the surface of the resist 720 becomes not greater than 100 nm, throughout the entire surface, and that they are closely contacted to each other once the thin film 440A is deformed elastically. Subsequently, the mask 400A and the plate 700 are brought into close contact with each other. Specifically, it is done essentially in the same matter as has been described with reference to the exposure apparatus 1, so that description will be omitted here.

The exposure process is carried out in the state described just above. More specifically, exposure light emitted from the light source unit 100 and having been transformed by the collimator lens 200 into parallel light, which has a polarization characteristic of circular polarization, is introduced into the pressurized vessel 610 through the light transmitting window 620. The light introduced into the vessel 610 passes through the mask 440A from the rear-surface side to the front-surface side thereof, that is, from the top to the bottom as viewed in FIG. 8, thereby to produce near-field light escaping from the pattern as defined by the small openings 432A of the thin film 440A. The near-field light scatters within the resist 720, to expose the resist 720. If the thickness of the resist 720 is sufficiently thin, the scattering of the near-field light within the resist 720 does not expand so widely, such that a pattern corresponding to the slits of the small openings 432A, which are smaller than the wavelength of the exposure light, can be transferred to the resist 720. After the exposure, while using the pressure adjusting system 600, the thin film 440 is separated (or peeled) from the resist 720 on the basis of elastic deformation.

As described above, the mask 400A is closely contacted to the resist 720 or substrate 710, and light having polarization component of circularly polarized light is used as the exposure light. With this arrangement, the intensity of the near-field light escaping from the small openings 432A becomes even such that, without the provision of a polarizer in the mask 400A, non-uniformness of exposure of the resist 720 can be reduced effectively.

### EXAMPLE 2

Now, a case where an exposure apparatus IA operates to transfer a pattern formed on a mask 400A in a batch process will be explained. For manufacture of a mask 400A, silicon wafer Si (100) was chosen for a mask supporting member 410A. Upon this Si substrate, SiN film as a mask base material 420A was formed with a thickness 500 nm, in accordance with LPCVD (Low Pressure Chemical Vapor Deposition) method. Further, upon the mask base material 420A, a Cr film as a light blocking film 430A was formed with a thickness 50 nm, in accordance with a sputtering method. Small openings 432A (opening diameter not greater than 100 nm) of a size not greater than the wavelength of exposure light, were formed on the light blocking film 430A into a desired pattern, by means of electron-beam lithographic method. In this embodiment, the small openings 432A have their lengthwise directions extending in arbitrary directions, as shown in FIG. 7.

Subsequently, at the surface on the opposite side of the light blocking film 430A, patterning with a size 26 mm×26 mm was carried out to that portion where the mask 400A should be produced. Then, SiN material in that portion was removed by RIE (Reactive Ion Etching) method using CF4 gas. The remaining SiN was used as an etching mask, the silicon was etched by use of an aqueous solution of 30 wt % potassium hydroxide, being warmed at 110° C., by which Si material only at that portion to be made into the mask 400A was removed. With the processes described above, a mask 400 supported by a silicon wafer was produced.

In this example, SiN is used as a base material 420A of the mask while Cr is used as a light blocking film 430A. However, the concept of the present invention is not limited to use of a particular material. As regards the base material 420A of the mask, preferably, it should be a material being transmissive to exposure light and also it should provide a sufficient mechanical strength to the thin film 440A. As regards the light blocking film 430A, on the other hand, preferably, it should be a material having no influence upon the plate 700 and also be a material which does not transmit light of the wavelength to be used for the exposure. Additionally, it may preferably have a thickness by which light can be attenuated sufficiently.

A mask 400A having been produced in the manner described above, is mounted into an exposure apparatus 1A shown in FIG. 9.

After this, in order to prepare close contact between the resist 720 (object to be exposed) and the mask 400A, an alignment operation is carried out to between the mask 400A and the substrate 700. Then, a compressed air is introduced by the pressure adjusting means 630 into the pressurized vessel 610 at a pressure 40 kPa, whereby a pressure difference is produced between the front surface and the rear surface of the mask 400A. Thus, the thin film 440A is flexed and close-contacted to the resist 720, uniformly at a clearance not greater than about 100 nm.

After the mask and the resist 720 are closely contacted to each other, light of linear polarization from an SAG (second harmonic generation) laser which emits a wavelength 860 nm, as the light source unit 100A, is projected which is then transformed into parallel light by a collimator lens 200. The resultant parallel light is then transformed through a quarter waveplate 310A into exposure light having polarization characteristic of circular polarization, and it is projected to the whole surface of the mask 400A. Exposure light thus projected on the mask 400A escapes from the small openings 432 of the mask 400A surface, and near-field light of uniform intensity is produced. With this near-field light, the pattern of the small openings 432A was transferred by batch exposure, to the whole surface of the resist 720 without exposure non-uniformness.

For separation of the mask 400A from the plate 700, the inside pressure of the pressurized vessel 610 was lowered by the pressure adjusting means 630 to a pressure lower than the atmospheric pressure approximately by 40 kPa, and then the mask 400A and the plate 700 were separated from each other.

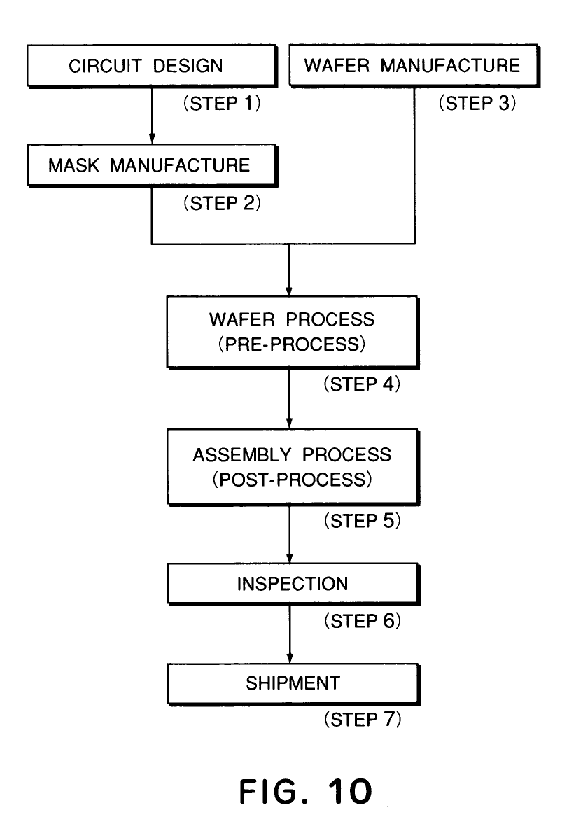

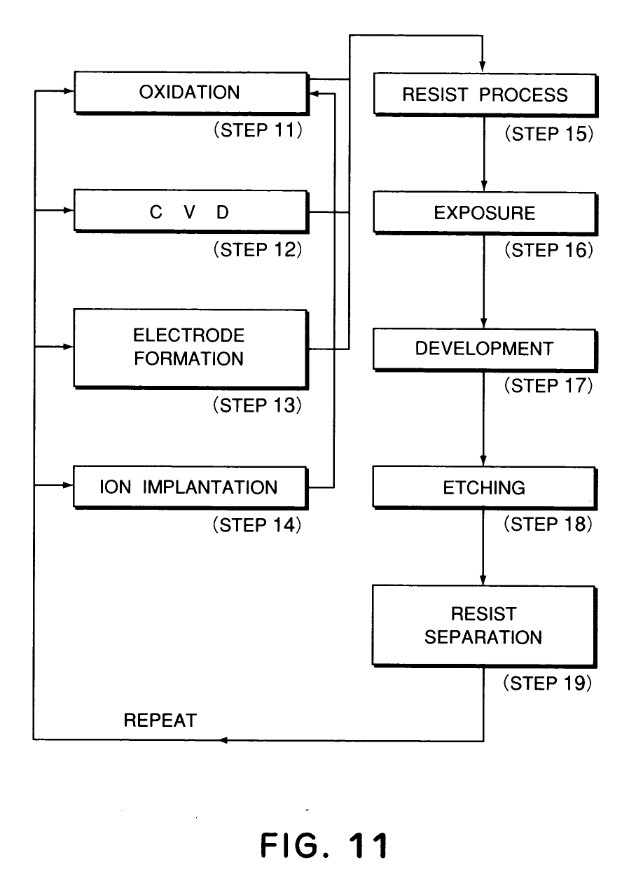

Next, referring to FIGS. 10 and 11, an embodiment of a device manufacturing method which uses an exposure apparatus 1 or 1A described above, will be explained.

FIG. 10 is a flow chart for explaining the procedure of manufacturing various microdevices such as semiconductor chips (e.g., ICs or LSIs), liquid crystal panels, or CCDs, for example. Step 1 is a design process for designing a circuit of a semiconductor device. Step 2 is a process for making a mask on the basis of the circuit pattern design. Step 3 is a process for preparing a wafer by using a material such as silicon. Stop 4 is a wafer process which is called a pre-process wherein, by using the thus prepared mask and wafer, a circuit is formed on the wafer in practice, in accordance with lithography. Step 5 subsequent to this is an assembling step which is called a post-process wherein the wafer having been processed at step 4 is formed Into semiconductor chips. This step includes an assembling (dicing and bonding) process and a packaging (chip sealing) process. Step 6 is an inspection step wherein an operation check, a durability check an so on, for the semiconductor devices produced by step 5, are carried out. With these processes, semiconductor devices are produced, and they are shipped (step 7).

FIG. 11 is a flow chart for explaining details of the wafer process. Step 11 is an oxidation process for oxidizing the surface of a wafer. Step 12 is a CVD process for forming an insulating film on the wafer surface. Step 13 is an electrode forming process for forming electrodes upon the wafer by vapor deposition. Step 14 is an ion implanting process for implanting ions to the wafer. Step 15 is a resist process for applying a resist (photosensitive material) to the wafer. Step 16 is an exposure process for printing, by exposure, the circuit pattern of the mask on the wafer through the exposure apparatus described above. Step 17 is a developing process for developing the exposed wafer. Step 18 is an etching process for removing portions other than the developed resist image. Step 19 is a resist separation process for separating the resist material remaining on the wafer after being subjected to the etching process. By repeating these processes, circuit patterns are superposedly formed on the wafer.

With these processes, high quality microdevices can be manufactured.

While some preferred embodiments and examples of the present invention have been described above, the invention is not confined to the details set forth and this application is intended to cover such modifications or changes as may come within the purposes of the improvements or the scope of the following claims.

What is claimed is:

1. An exposure method, comprising the steps of:
closely contacting, to a workpiece, a mask having an opening formed with lengthwise directions extending in orthogonal directions; and
projecting, onto the mask, exposure light being polarized in a direction other than the directions mentioned above.

2. A method according to claim 1, further comprising detecting the lengthwise direction of the opening of the mask, and generating the exposure step on the basis of the detection.

3. A method according to claim 1, wherein in said projecting step exposure light being polarized in a direction with an angle of approximately 45° with respect to the lengthwise direction of the opening, is projected onto the mask.

4. A method according to claim 1, wherein the mask has an opening formed only in mutually orthogonal directions.

5. An exposure mask, comprising:
a mask base material supported by a substrate and being effective to transmit exposure light therethrough;
a light blocking film formed on the mask base material and being effective to block the exposure light; and
an opening formed in the light blocking film and having its lengthwise directions extending in mutually orthogonal directions.

6. An exposure mask according to claim 5, further comprising a mark formed in the light blocking film, which mark bears information regarding the lengthwise direction of the opening.

7. An exposure apparatus based on near-field light, comprising;
light source means for emitting light to illuminate a mask having an opening formed with lengthwise directions extending in orthogonal directions; and
a polarization system disposed between the mask and said light source means, for polarizing the light in a direction other than the directions mentioned above.

8. An apparatus according to claim 7, further comprising a detecting system for detecting the lengthwise direction of the opening, wherein said detecting system includes polarization control means for controlling the polarization direction of the light at an angle of 45° with respect to the lengthwise direction of the opening, on the basis of the detection made by said detecting system.

9. An apparatus according to claim 7, wherein the mask has an opening formed only in mutually orthogonal directions.

10. An exposure apparatus, comprising:
a mask as recited in claim 5 or 6; and
projecting means for projecting, to the mask, light having a polarization direction with an angle of approximately 45° with respect to the lengthwise direction of the opening formed in the mask.

11. In an exposure apparatus based on near-field light, the improvements residing in circularly polarized light projecting means for projecting, onto a mask having an opening formed with lengthwise directions extending in plural directions, exposure light having a circularly polarized component.

12. An apparatus according to claim 11, therein said circularly polarized light projecting means includes a light source unit for emitting light having a polarization component of circular polarization.

13. An apparatus according to claim 11, wherein said circularly polarized light projecting means includes a light source unit for projecting light having a polarization component of linear polarization, and a converting element for converting the linear polarization component of the light into a circular polarization component.

14. An apparatus according to claim 11, wherein said circularly polarized light projecting means includes a light source unit for projecting light having a random polarization component, a first converting element for converting the random polarization component of the light into a predetermined linear polarization component, and a second converting element for converting the predetermined linear polarization component into a circular polarization component.

15. An exposure method, comprising the steps of:
closely contacting, to a workpiece, a mask having an opening formed with lengthwise directions extending in plural directions; and
projecting, onto the mask, light having a polarization component of circular polarization.

16. A device manufacturing method, comprising the steps of:
exposing a workpiece by use of an exposure apparatus as recited in any one of claims 7-14; and
performing a predetermined process to the exposed workpiece.
